(19) United States
(12) Patent Application Publication
(10) Pub. No.: US 2020/0090907 A1
(43) Pub. Date: Mar. 19, 2020

(54) SYSTEMS AND PROCESSES FOR PLASMA TUNING

(71) Applicant: Applied Materials, Inc., Santa Clara, CA (US)

(72) Inventors: Junghoon Kim, Santa Clara, CA (US); Tae Cho, San Jose, CA (US); Theodore Wou, San Jose, CA (US); Soonam Park, Sunnyvale, CA (US); Dmitry Lubomirsky, Cupertino, CA (US)

(73) Assignee: Applied Materials, Inc., Santa Clara, CA (US)

(21) Appl. No.: 16/134,200

(22) Filed: Sep. 18, 2018

(51) Int. Cl. H01J 37/32; C23C 16/513; H01J 37/305; H01L 21/3065

(52) U.S. Cl. CPC H01J 37/32183; C23C 16/513; H01L 21/3065; H01J 37/32724; H01J 37/3053

(57) ABSTRACT

Systems and methods may be used to enact plasma tuning. Exemplary semiconductor processing chambers may include a pedestal positioned within the chamber and configured to support a substrate. The pedestal may include an electrode operable to form a plasma within a processing region of the semiconductor processing chamber, with the processing region at least partially defined by the pedestal. The pedestal may include a heater embedded within the pedestal, and the heater may be coupled with a power supply. An RF filter may be coupled between the power supply and the heater. A shunt capacitor may also be coupled between the RF filter and the heater.

### TECHNICAL FIELD

The present technology relates to semiconductor systems, processes, and equipment. More specifically, the present technology relates to systems and methods for tuning plasma characteristics within a processing chamber.

### BACKGROUND

Integrated circuits are made possible by processes which produce intricately patterned material layers on substrate surfaces. Producing patterned material on a substrate requires controlled methods of formation and removal of materials. Chemical deposition and etching is used for a variety of purposes including forming structures and layers, transferring a pattern in photoresist into underlying layers, thinning layers, or thinning lateral dimensions of features already present on the surface. Deposition and etching may be performed with or without different types of enhancement. For example, temperature, pressure, and chemical characteristics may be used to produce or remove materials. Additionally, plasma may be used to enhance one or more precursors, which may facilitate deposition or etching by producing more reactive species.

As device and structure sizes continue to shrink, uniformity may become an issue for a process, and the difficulty of ensuring similar amounts of material are formed or removed across a surface of a substrate may be increased. Modifying components within a system may improve flow profiles within a chamber, as well as adjusting chamber conditions, which may affect flow dynamics. Generated plasma within a processing chamber may also have non-uniform volumes, which may affect the distribution of reactive species within regions of the chamber.

Thus, there is a need for improved systems and methods that can be used to produce high quality devices and structures. These and other needs are addressed by the present technology.

### SUMMARY

Systems and methods may be used to enact plasma tuning. Exemplary semiconductor processing chambers may include a pedestal positioned within the chamber and configured to support a substrate. The pedestal may include an electrode operable to form a plasma within a processing region of the semiconductor processing chamber, with the processing region at least partially defined by the pedestal. The pedestal may include a heater embedded within the pedestal, and the heater may be coupled with a power supply. An RF filter may be coupled between the power supply and the heater. A shunt capacitor may also be coupled between the RF filter and the heater.

In some embodiments, the shunt capacitor may include a variable capacitor coupled with a motor configured to adjust a capacitance of the variable capacitor. The motor may be controlled by a control system configured to perform real-time adjustments to impedance of the heater. The heater may include a resistive heater including an inlet line and an outlet line, and the inlet line and the outlet line may each be coupled with a variable capacitor. The inlet line and the outlet line may each be electrically coupled with a single variable capacitor. The power supply may include an AC power supply. The electrode may be coupled with an RF generator configured to operate at about 13.56 MHz. The heater may be a first heater, and the semiconductor processing system may also include a second heater radially inward of the first heater. The RF filter may be a first RF filter, the shunt capacitor may be a first shunt capacitor, and the second heater may be coupled with a second RF filter and a second shunt capacitor individually adjustable separately from the first shunt capacitor. The system may also include four heaters each individually electrically coupled with a separate RF filter and a separate shunt capacitor.

The present technology may also encompass methods of forming a plasma within a semiconductor processing chamber. The methods may include flowing a precursor into a processing region of the semiconductor processing chamber. The processing region may be at least partially defined by a pedestal configured to support a substrate. The pedestal may include an electrode operable to form a plasma within the processing region of the semiconductor processing chamber, and the processing region may be at least partially defined by the pedestal. The pedestal may include a heater embedded within the pedestal, and the heater may be coupled with a power supply. An RF filter may be coupled between the power supply and the heater, and a shunt capacitor may be coupled between the RF filter and the heater. The methods may also include forming a plasma of the precursor to produce plasma effluents.

In some embodiments, the methods may also include operating a motor coupled with the shunt capacitor to adjust a capacitance of the shunt capacitor. Increasing the capacitance of the shunt capacitor may reduce an impedance at the heater. The heater may be disposed within the pedestal proximate a radial edge of the pedestal. Increasing the capacitance of the shunt capacitor may reduce a thickness of an envelope of the plasma proximate the radial edge of the pedestal. The pedestal may include a ceramic, and the electrode may be coupled with an RF generator. The RF generator may be configured to operate at 13.56 MHz. The methods may also include a plurality of heaters, where each heater of the plurality of heaters may be coupled with a separate RF filter, and a separate shunt capacitor may be positioned between each heater and RF filter. The shunt capacitor may be coupled as a bypass between the heater and the RF filter. The precursor may be or include a halogen-containing precursor.

Some embodiments of the present technology may also encompass a semiconductor processing system. The system may include a pedestal positioned within a semiconductor processing chamber and configured to support a substrate. The pedestal may include an electrode operable to form a plasma within a processing region of the semiconductor processing chamber, and the processing region may be at least partially defined by the pedestal. The pedestal may include a ceramic, and the electrode may be coupled with an RF generator configured to operate at 13.56 MHz. The pedestal may include a heater embedded within the pedestal, which may be coupled with an AC power supply. An RF filter may be coupled between the AC power supply and the heater, and a shunt capacitor may be coupled between the RF filter and the heater. The shunt capacitor may be electrically coupled as a bypass between the RF filter and the heater.

Such technology may provide numerous benefits over conventional systems and techniques. For example, by incorporating a shunt capacitor, the plasma envelope may be modified in regions to produce a more uniform volume. Additionally, aspects of the present technology may facilitate retrofitting components into existing chambers, because the components may not include modification, or may include minimal modifications to chamber components. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary processing chamber according to some embodiments of the present technology.

FIG. 3 shows a schematic partial cross-sectional view of an exemplary processing chamber according to some embodiments of the present technology.

FIG. 4 shows a schematic partial cross-sectional view of an exemplary processing system according to some embodiments of the present technology.

FIGS. 5A-5B illustrate schematic views of heater elements according to some embodiments of the present technology.

FIG. 6 shows a schematic partial cross-sectional view of an exemplary processing chamber according to some embodiments of the present technology.

FIG. 7 illustrates exemplary operations in methods according to some embodiments of the present technology.

FIG. 8 shows a schematic partial cross-sectional view of an exemplary processing system according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Deposition and etching operations may involve forming a local plasma, such as a plasma within a processing region in which a substrate may be housed in a semiconductor processing chamber. One exemplary formation may include forming a bias plasma between an electrode within a pedestal on which the substrate is supported and a chamber component, such as a lid or showerhead, for example. The chamber component may be grounded and allow formation of plasma within the processing region. Chamber sidewalls may also be grounded, and may be in closer proximity to the electrode of the pedestal than the chamber component operating as a ground electrode. This may cause a non-uniform plasma volume to be produced within the chamber.

For example, during some plasma etching operations, a plasma may be formed of a precursor including highly electronegative materials. Continuing the example, halogen-containing precursors or chalcogen-containing precursors may include atoms having higher electronegativity. When a plasma is formed of these precursors, the distance to ground may affect a shape of the internal plasma volume, such as by creating wider and narrower regions. These non-uniformities may produce regions of higher concentration for the reactive species, such as at radial edges of the plasma volume, which may be in close proximity to chamber sidewalls. In an etch process this may produce increased etching along edge regions of the substrate, and in deposition processes this may increase the amount of deposition at the edges. Accommodating the enhanced edge effects may be difficult, and conventional processes may have resulted in lost space at edge regions on a substrate.

The present technology may overcome these issues by providing a system that allows impedance tuning to modify the plasma volume. By reducing impedance at edge regions of the pedestal, for example, a more uniform plasma volume may be produced. This may increase process uniformity, and by utilizing variable components, may allow precise control over operation to adjust for particular precursors or process conditions.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes alone.

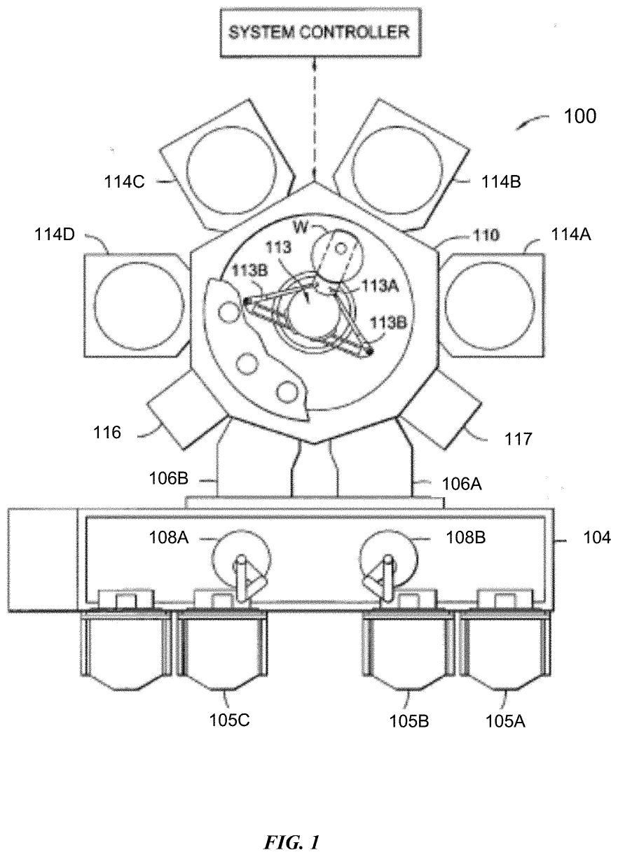

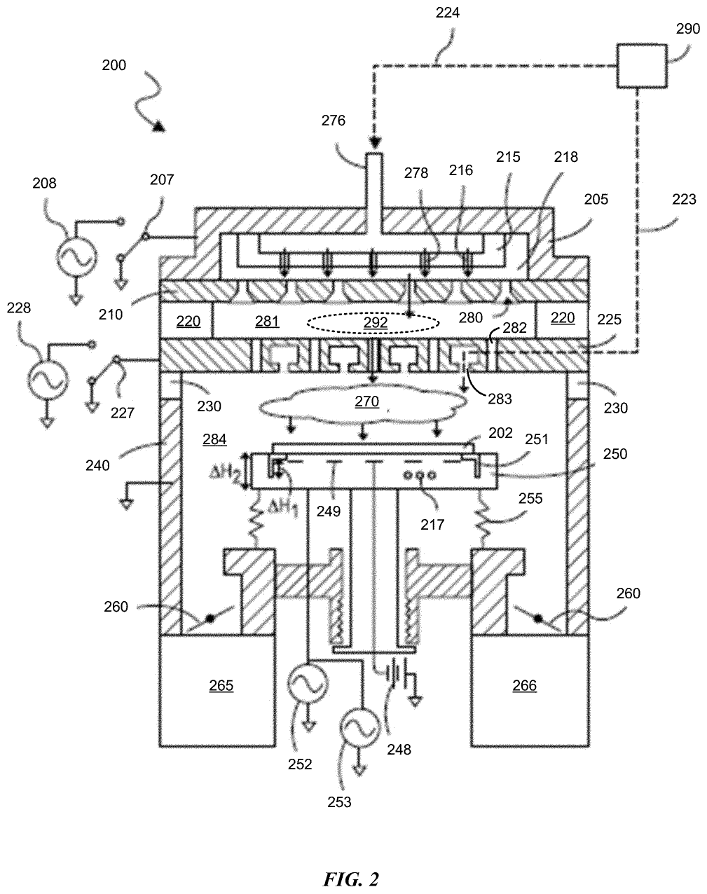

FIG. 1 shows a top plan view of one embodiment of a processing system 100 of deposition, etching, baking, and curing chambers according to embodiments. The processing tool 100 depicted in FIG. 1 may contain a plurality of process chambers, 114a-d, a transfer chamber 110, a service chamber 116, an integrated metrology chamber 117, and a pair of load lock chambers 106a-b. The process chambers may include structures or components similar to those described in relation to FIG. 2, as well as additional processing chambers.

To transport substrates among the chambers, the transfer chamber 110 may contain a robotic transport mechanism 113. The transport mechanism 113 may have a pair of substrate transport blades 113a attached to the distal ends of extendible arms 113B, respectively. The blades 113a may be used for carrying individual substrates to and from the process chambers. In operation, one of the substrate transport blades such as blade 113a of the transport mechanism 113 may retrieve a substrate W from one of the load lock chambers such as chambers 106a-b and carry substrate W to a first stage of processing, for example, an etching process as described below in chambers 114a-d. If the chamber is occupied, the robot may wait until the processing is complete and then remove the processed substrate from the chamber with one blade 113a and may insert a new substrate with a second blade (not shown). Once the substrate is processed, it may then be moved to a second stage of processing. For each move, the transport mechanism 113 generally may have one blade carrying a substrate and one blade empty to execute a substrate exchange. The transport mechanism 113 may wait at each chamber until an exchange can be accomplished.

Once processing is complete within the process chambers, the transport mechanism 113 may move the substrate W from the last process chamber and transport the substrate W to a cassette within the load lock chambers 106a-b. From the load lock chambers 106a-b, the substrate may move into a factory interface 104. The factory interface 104 generally may operate to transfer substrates between pod loaders 105a-d in an atmospheric pressure clean environment and the load lock chambers 106a-b. The clean environment in factory interface 104 may be generally provided through air filtration processes, such as HEPA filtration, for example. Factory interface 104 may also include a substrate orienter/aligner (not shown) that may be used to properly align the substrates prior to processing. At least one substrate robot, such as robots 108a-b, may be positioned in factory interface 104 to transport substrates between various positions/locations within factory interface 104 and to other locations in communication therewith. Robots 108a-b may be configured to travel along a track system within factory interface 104 from a first end to a second end of the factory interface 104.

The processing system 100 may further include an integrated metrology chamber 117 to provide control signals, which may provide adaptive control over any of the processes being performed in the processing chambers. The integrated metrology chamber 117 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Turning now to FIG. 2 is shown a cross-sectional view of an exemplary process chamber system 200 according to the present technology. Chamber 200 may be used, for example, in one or more of the processing chamber sections 114 of the system 100 previously discussed Generally, the etch chamber 200 may include a first capacitively-coupled plasma source to implement an ion milling operation and a second capacitively-coupled plasma source to implement an etching operation and to implement an optional deposition operation. The ion milling operation may also be called a modification operation. The chamber 200 may include grounded chamber walls 240 surrounding a chuck 250. In embodiments, the chuck 250 may be an electrostatic chuck that clamps the substrate 202 to a top surface of the chuck 250 during processing, though other clamping mechanisms as would be known may also be utilized. The chuck 250 may include an embedded heat exchanger coil 217. In the exemplary embodiment, the heat exchanger coil 217 includes one or more heat transfer fluid channels through which heat transfer fluid, such as an ethylene glycol/water mix, may be passed to control the temperature of the chuck 250 and ultimately the temperature of the substrate 202.

The chuck 250 may include a mesh 249 coupled to a high voltage DC supply 248 so that the mesh 249 may carry a DC bias potential to implement the electrostatic clamping of the substrate 202. The chuck 250 may be coupled with a first RF power source and in one such embodiment, the mesh 249 may be coupled with the first RF power source so that both the DC voltage offset and the RF voltage potentials are coupled across a thin dielectric layer on the top surface of the chuck 250. In the illustrative embodiment, the first RF power source may include a first and second RF generator 252, 253. The RF generators 252, 253 may operate at any industrially utilized frequency, however in the exemplary embodiment the RF generator 252 may operate at 60 MHz to provide advantageous directionality. Where a second RF generator 253 is also provided, the exemplary frequency may be 2 MHz.

With the chuck 250 to be RF powered, an RF return path may be provided by a first showerhead 225. The first showerhead 225 may be disposed above the chuck to distribute a first feed gas into a first chamber region 284 defined by the first showerhead 225 and the chamber wall 240. As such, the chuck 250 and the first showerhead 225 form a first RF coupled electrode pair to capacitively energize a first plasma 270 of a first feed gas within a first chamber region 284. A DC plasma bias, or RF bias, resulting from capacitive coupling of the RF powered chuck may generate an ion flux from the first plasma 270 to the substrate 202, e.g., Ar ions where the first feed gas is Ar, to provide an ion milling plasma. The first showerhead 225 may be grounded or alternately coupled with an RF source 228 having one or more generators operable at a frequency other than that of the chuck 250, e.g., 13.56 MHz or 60 MHz. In the illustrated embodiment the first showerhead 225 may be selectably coupled to ground or the RF source 228 through the relay 227 which may be automatically controlled during the etch process, for example by a controller (not shown). In disclosed embodiments, chamber 200 may not include showerhead 225 or dielectric spacer 220, and may instead include only baffle 215 and showerhead 210 described further below.

As further illustrated in the figure, the etch chamber 200 may include a pump stack capable of high throughput at low process pressures. In embodiments, at least one turbo molecular pump 265, 266 may be coupled with the first chamber region 284 through one or more gate valves 260 and disposed below the chuck 250, opposite the first showerhead 225. The turbo molecular pumps 265, 266 may be any commercially available pumps having suitable throughput and more particularly may be sized appropriately to maintain process pressures below or about 10 mTorr or below or about 5 mTorr at the desired flow rate of the first feed gas, e.g., 50 to 500 sccm of Ar where argon is the first feedgas. In the embodiment illustrated, the chuck 250 may form part of a pedestal which is centered between the two turbo pumps 265 and 266, however in alternate configurations chuck 250 may be on a pedestal cantilevered from the chamber wall 240 with a single turbo molecular pump having a center aligned with a center of the chuck 250.

Disposed above the first showerhead 225 may be a second showerhead 210. In one embodiment, during processing, the first feed gas source, for example, Argon delivered from gas distribution system 290 may be coupled with a gas inlet 276, and the first feed gas flowed through a plurality of apertures 280 extending through second showerhead 210, into the second chamber region 281, and through a plurality of apertures 282 extending through the first showerhead 225 into the first chamber region 284. An additional flow distributor or baffle 215 having apertures 278 may further distribute a first feed gas flow 216 across the diameter of the etch chamber 200 through a distribution region 218. In an alternate embodiment, the first feed gas may be flowed directly into the first chamber region 284 via apertures 283 which are isolated from the second chamber region 281 as denoted by dashed line 223.

Chamber 200 may additionally be reconfigured from the state illustrated to perform an etching operation. A secondary electrode 205 may be disposed above the first showerhead 225 with a second chamber region 281 there between. The secondary electrode 205 may further form a lid or top plate of the etch chamber 200. The secondary electrode 205 and the first showerhead 225 may be electrically isolated by a dielectric ring 220 and form a second RF coupled electrode pair to capacitively discharge a second plasma 292 of a second feed gas within the second chamber region 281. Advantageously, the second plasma 292 may not provide a significant RF bias potential on the chuck 250. At least one electrode of the second RF coupled electrode pair may be coupled with an RF source for energizing an etching plasma. The secondary electrode 205 may be electrically coupled with the second showerhead 210. In an exemplary embodiment, the first showerhead 225 may be coupled with a ground plane or floating and may be coupled to ground through a relay 227 allowing the first showerhead 225 to also be powered by the RF power source 228 during the ion milling mode of operation. Where the first showerhead 225 is grounded, an RF power source 208, having one or more RF generators operating at 13.56 MHz or 60 MHz, for example, may be coupled with the secondary electrode 205 through a relay 207 which may allow the secondary electrode 205 to also be grounded during other operational modes, such as during an ion milling operation, although the secondary electrode 205 may also be left floating if the first showerhead 225 is powered.

A second feed gas source, such as nitrogen trifluoride, and a hydrogen source, such as ammonia, may be delivered from gas distribution system 290, and coupled with the gas inlet 276 such as via dashed line 224. In this mode, the second feed gas may flow through the second showerhead 210 and may be energized in the second chamber region 281. Reactive species may then pass into the first chamber region 284 to react with the substrate 202. As further illustrated, for embodiments where the first showerhead 225 is a multi-channel showerhead, one or more feed gases may be provided to react with the reactive species generated by the second plasma 292. In one such embodiment, a water source may be coupled with the plurality of apertures 283. Additional configurations may also be based on the general illustration provided, but with various components reconfigured. For example, flow distributor or baffle 215 may be a plate similar to the second showerhead 210, and may be positioned between the secondary electrode 205 and the second showerhead 210. As any of these plates may operate as an electrode in various configurations for producing plasma, one or more annular or other shaped spacer may be positioned between one or more of these components, similar to dielectric ring 220. Second showerhead 210 may also operate as an ion suppression plate in embodiments, and may be configured to reduce, limit, or suppress the flow of ionic species through the second showerhead 210, while still allowing the flow of neutral and radical species. One or more additional showerheads or distributors may be included in the chamber between first showerhead 225 and chuck 250. Such a showerhead may take the shape or structure of any of the distribution plates or structures previously described. Also, in embodiments a remote plasma unit (not shown) may be coupled with the gas inlet to provide plasma effluents to the chamber for use in various processes.

In an embodiment, the chuck 250 may be movable along the distance H2 in a direction normal to the first showerhead 225. The chuck 250 may be on an actuated mechanism surrounded by a bellows 255, or the like, to allow the chuck 250 to move closer to or farther from the first showerhead 225 as a means of controlling heat transfer between the chuck 250 and the first showerhead 225, which may be at an elevated temperature of 80° C.-150° C., or more. As such, an etch process may be implemented by moving the chuck 250 between first and second predetermined positions relative to the first showerhead 225. Alternatively, the chuck 250 may include a lifter 251 to elevate the substrate 202 off a top surface of the chuck 250 by distance H1 to control heating by the first showerhead 225 during the etch process. In other embodiments, where the etch process is performed at a fixed temperature such as about 90-110° C. for example, chuck displacement mechanisms may be avoided. A system controller (not shown) may alternately energize the first and second plasmas 270 and 292 during the etching process by alternately powering the first and second RF coupled electrode pairs automatically.

The chamber 200 may also be reconfigured to perform a deposition operation. A plasma 292 may be generated in the second chamber region 281 by an RF discharge which may be implemented in any of the manners described for the second plasma 292. Where the first showerhead 225 is powered to generate the plasma 292 during a deposition, the first showerhead 225 may be isolated from a grounded chamber wall 240 by a dielectric spacer 230 so as to be electrically floating relative to the chamber wall. In the exemplary embodiment, an oxidizer feed gas source, such as molecular oxygen, may be delivered from gas distribution system 290, and coupled with the gas inlet 276. In embodiments where the first showerhead 225 is a multi-channel showerhead, any silicon-containing precursor, such as OMCTS for example, may be delivered from gas distribution system 290, and directed into the first chamber region 284 to react with reactive species passing through the first showerhead 225 from the plasma 292. Alternatively the silicon-containing precursor may also be flowed through the gas inlet 276 along with the oxidizer. Chamber 200 is included as a general chamber configuration that may be utilized for various operations discussed in reference to the present technology. The chamber is not to be considered limiting to the technology, but instead to aid in understanding of the processes described. Several other chambers known in the art or being developed may be utilized with the present technology including any chamber produced by Applied Materials Inc. of Santa Clara, Calif., or any chamber that may perform the techniques described in more detail below.

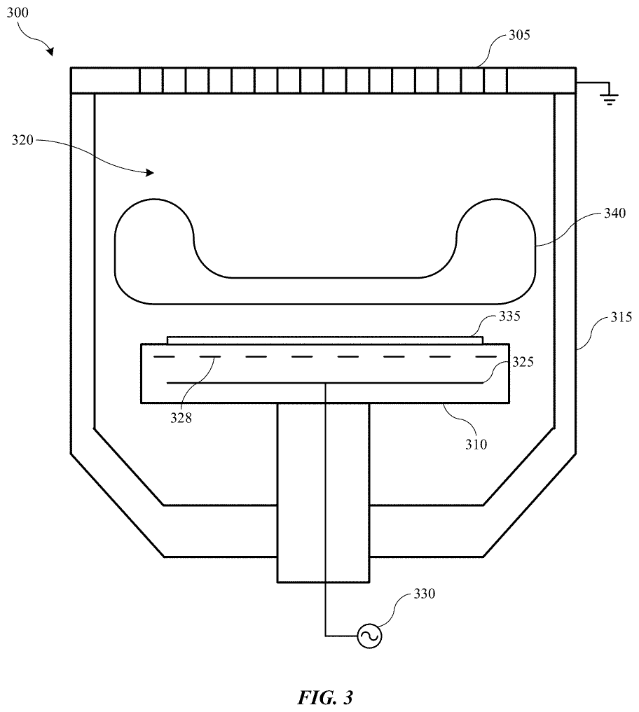

Turning to FIG. 3 is shown a partial schematic view of a processing chamber 300 according to embodiments of the present technology. FIG. 3 may include one or more components discussed above with regard to FIG. 2, and may illustrate further details relating to that chamber. The chamber 300 may be used to perform semiconductor processing operations including modification and etching as previously described. Chamber 300 may show a partial view of a processing region of a semiconductor processing system, and may not include all of the components, such as additional lid stack components previously described that are understood to be incorporated in some embodiments of chamber 300.

As noted, FIG. 3 may illustrate a portion of a processing chamber 300. The chamber 300 may include a showerhead 305, as well as a substrate support 310. Along with chamber sidewalls 315, the showerhead 305 and the substrate support 310 may define a substrate processing region 320. The substrate support may include an electrode 325 disposed within the puck, which may be or include a dielectric material in some embodiments. Electrode 325 may be electrically coupled with a power source 330. Power source 330 may be configured to provide energy or voltage to the electrode 325. This may form a bias plasma of a precursor within the processing region 320 of the semiconductor processing chamber 300. Ions or other radical species formed within the processing region may be directed to a substrate seated on the substrate support. This may allow etching or modification to be performed on a surface of a substrate 335. A heater 328 may also be disposed within the substrate support 310, and may be used to control a temperature of the substrate.

The precursor utilized to form the plasma may affect the volumetric profile of the plasma. For example, when halogen-containing precursors are delivered into processing region 320 and a plasma is generated, highly electronegative materials are distributed. Because chamber sidewalls 315 may be closer to electrode 325 at a radial edge of the pedestal than showerhead 305, the shorter path to ground may affect the distribution of plasma effluents, and the volumetric profile of the plasma envelope. For example, as illustrated in an exaggerated form for the ease of discussion, plasma volume 340 may include a distribution where an outer edge of the volume has an expanded thickness over an interior region. This may concentrate more radical species along the periphery, which may enhance an etch or deposition process along an outer region of substrate 335 causing inconsistencies across the substrate.

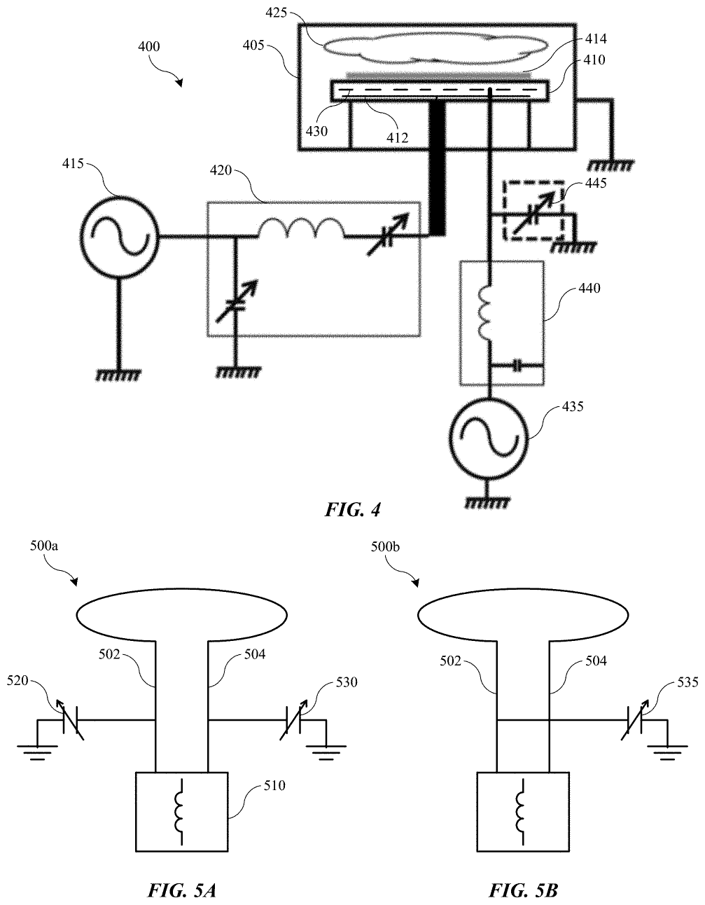

FIG. 4 shows a schematic partial cross-sectional view of an exemplary processing system 400 according to some embodiments of the present technology. FIG. 4 may illustrate a partial view of a chamber 405, which may be similar to FIG. 3, and may include any of the components of FIG. 3 or FIG. 2 in some embodiments. For example, chamber 405 may include a pedestal 410, which includes an electrode 412 disposed within the puck on which a substrate 414 may be supported. In some embodiments the pedestal or top puck of the pedestal may be or include a dielectric material. The electrode may be coupled with a power source 415, such as an RF generator, which may be operated through an RF match 420 to form a plasma 425 within the chamber 405. The RF generator may be operated at any number of frequencies from about 1 MHz to about 80 MHz or higher, including at any individual frequency or smaller range within this stated range, including at fractions such as 13.56 MHz. A chamber lid or internal component such as a showerhead may be operated as a ground electrode to define the processing region with the pedestal where the plasma volume may be formed.

A heater 430 may also be disposed within the pedestal as previously described. The heater 430 may be coupled with a power source 435, which may be an AC power source or other power source. In some embodiments both a coupling for the power source 415 and a coupling for the power source 435 may extend through pedestal 410, such as through the stem extending into the chamber. The couplings may be electrically separated from one another, and may extend in a coaxial arrangement relative to one another to limit or prevent electrical contact between the components. Heater 430 may be a resistive heater, and may be a coil disposed within the pedestal. In some embodiments multiple coils may be positioned concentrically within the pedestal to allow independent temperature control of multiple regions of the pedestal. For example, in some embodiments there may be at least one, two, three, four, five, six, or more heater coils disposed radially outward from one another within the pedestal. Additionally, an RF filter 440 may be positioned and electrically coupled between the power source 435 and the heater 430 to control interference along the line.

As previously explained, when plasma operations are performed, the plasma envelope may not be characterized by a uniform geometry depending on the precursors used and the chamber conditions. When this occurs, non-uniform processes may be performed due to concentrations of plasma species in locations such as about a periphery of the substrate. This radial non-uniformity may occur due to, among other reasons, a shorter distance to ground at an edge region to the chamber sidewalls as opposed to the lid or showerhead operating as a ground electrode. Electronegative species may cause stronger e-field distributions at the edges, which may distort the plasma volume as previously explained. Because the precursor may contribute to the effect, redistributing the plasma profile to a more uniform geometry may be difficult.

However, the present technology may enable reducing the plasma profile at specific regions by incorporating a shunt capacitor 445 between the RF filter and the heater. The shunt capacitor may allow an amount of current to pass to ground, and increasing the capacitance of the shunt capacitor may reduce the impedance along the heater coil. The shunt capacitor 445 may be a variable capacitor in some embodiments, which may allow tuning of the capacitance to occur and afford accommodation of different precursors and chamber environments. A motor may be coupled with the variable capacitor, which may allow a remote control source, such as a control system or computer, to adjust the capacitance in real time during processing operations.

Adjusting the capacitance may allow enhancement or reduction of impedance at particular regions of the pedestal associated with a correspondingly positioned heater coil. For example, by reducing impedance at a heater coil disposed near the periphery of the pedestal, such as by increasing capacitance of the shunt capacitor and transferring additional current to ground, an outer zone of the plasma volume may be reduced. Accordingly, a more uniform plasma envelope may be formed, which may increase uniformity of a process. The reduced impedance may increase processing time by reducing overall plasma within the processing chamber, however by providing a more uniform plasma distribution and performing processing for longer periods of time, similar etch or deposition amounts may be produced, while enhancing uniformity of the processing.

For example, by modifying the plasma volume in some embodiments by varying impedance along certain zones, the plasma envelope proximate a periphery of the processing region, or an exterior edge of the plasma envelope, may be characterized by a height that is within about 50% of the height of the plasma envelope along a central axis of the processing region. Hence, an envelope characterized by a height along a central axis of two centimeters, may also be characterized by a height of three centimeters or less at a periphery of the plasma envelope. In some embodiments a radial edge of the plasma envelope may be characterized by a height that differs by less than or about 40% of a height along a central axis through the processing region, and may differ by less than or about 30% of the height, less than or about 20% of the height, less than or about 10% of the height, less than or about 5% of the height, less than or about 1% of the height, or may be substantially or essentially equivalent to the height of the plasma envelope along a central axis through the processing region. This may produce processing having uniform operations at a periphery of a substrate within any of these percentages of processing at a central area of the substrate as well.

The shunt capacitor may be incorporated within the heater line at any position. In some embodiments, impedance at the heater may be substantially similar to impedance at a position immediately downstream of the RF filter 440. Accordingly the shunt capacitor may be incorporated further upstream from the chamber. This may allow limited modifications or no modifications to components within the processing chamber, and may allow the shunt capacitor to be incorporated externally to the chamber. This may facilitate retrofit operations, and may not require redesigns of chamber internal components.

FIGS. 5A-5B illustrate schematic views of heater elements 500 according to some embodiments of the present technology. As shown in FIG. 5A, heater element 500a may illustrate one exemplary design of a heater coil incorporated in an exemplary pedestal, such as any of the previously described chambers or systems. Heater element 500a may be a resistive heater element having an inlet line 502 and an outlet line 504. Heater element 500a may be one of several heating elements, and may not be illustrated to scale. For example, in some embodiments, multiple heater element lines may extend together through a pedestal stem before branching to the specific coil within the pedestal. Despite being part of the same circuit, each of the inlet line and outlet line may be filtered by RF filter 510.

As illustrated in FIG. 5A, inlet line 502 may be coupled with a variable capacitor 520, and outlet line 504 may be coupled with a variable capacitor 530. In an alternative construction, as illustrated in FIG. 5B, both inlet line 502 and outlet line 504 of heater element 500b may be electrically coupled with a single variable capacitor 535. In either coupling scheme, the variable capacitor may be coupled as a tee to ground, and may not be coupled in series between the RF filter and heater as the capacitor may block the AC current from passing to the heater.

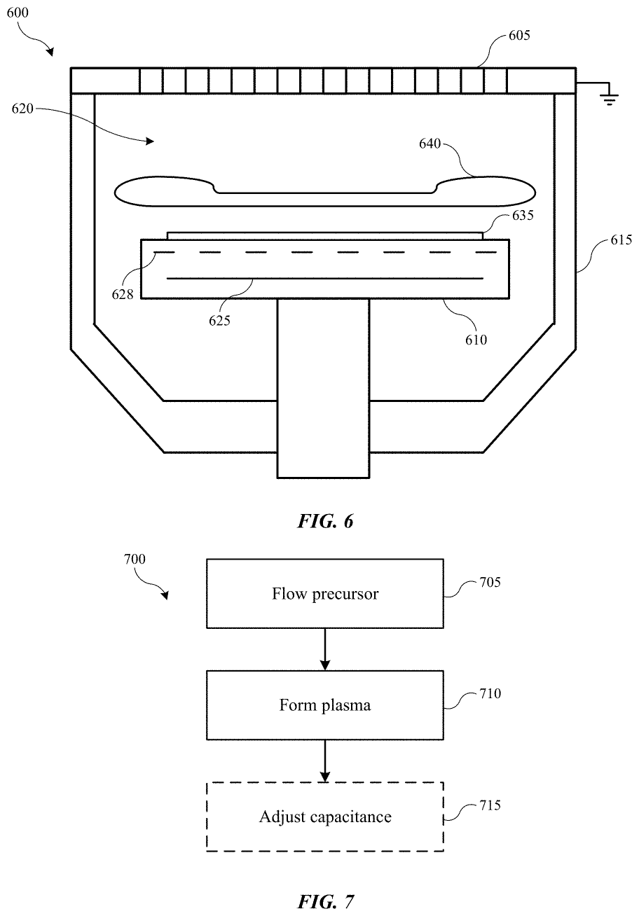

FIG. 6 shows a schematic partial cross-sectional view of an exemplary processing chamber 600 according to some embodiments of the present technology. Chamber 600 may be similar to chamber 300 described previously, and may include a showerhead 605, as well as a substrate support 610. Along with chamber sidewalls 615, the showerhead 605 and the substrate support 610 may define a substrate processing region 620. The substrate support may include an electrode 625 disposed within the puck, which may be or include a dielectric material in some embodiments. Electrode 625 may be electrically coupled with a power source as previously described, and which may provide energy or voltage to the electrode 625 to form a bias plasma 640 of a precursor within the processing region 620 of the semiconductor processing chamber 600. A plasma process may be performed on a surface of a substrate 635 as described above. Also, a heater 628 may be disposed within the substrate support 610, and may be used to control a temperature of the substrate as discussed previously.

FIG. 6 may illustrate an effect of utilizing a system as illustrated in FIGS. 4 and 5 to shunt current from an outer zone of the heater utilizing a capacitor, which may reduce the impedance through the heater, and flatten the plasma profile along an exterior region of the pedestal. This may reduce the effects of the plasma operation, and increase uniformity of the process performed across the substrate 635. By reducing the impedance, plasma effluents may be less concentrated about the exterior regions, and a more uniform distribution of effluents may be afforded.

The chambers and components of the present technology may be used in a variety of processes in which plasma may be formed by a bias plasma in the processing region of the chamber. FIG. 7 illustrates exemplary operations in a method 700 according to some embodiments of the present technology. Method 700 may be performed in any of the chambers previously described, and may include any of the components or characteristics discussed above, which may produce a more uniform plasma profile. The methods may include flowing a precursor into a processing region of a semiconductor processing chamber at operation 705. The chamber may include a pedestal as discussed above including a heater electrically coupled with a variable capacitor and RF filter. The methods may also include forming a plasma of the precursor at operation 710, which may produce plasma effluents that may be used to process a substrate as discussed previously. The methods may also include adjusting a capacitance of a shunt capacitor electrically coupled with the heater to modify a plasma profile within the chamber at optional operation 715. For example, a motor may be engaged by a control system to modulate the capacitance of the shunt capacitor, where increasing the capacitance may reduce the impedance at the heater as previously described, and which may reduce the plasma envelope at an exterior region of the processing region.

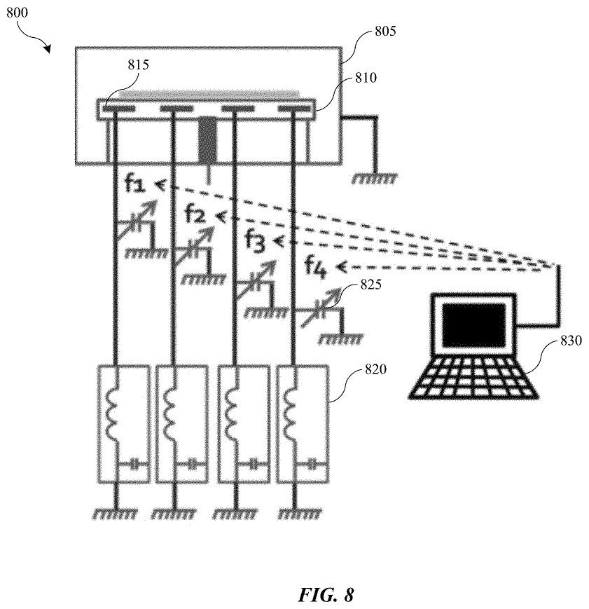

FIG. 8 shows a schematic partial cross-sectional view of an exemplary processing system 800 according to some embodiments of the present technology. FIG. 8 may include any of the components described above for any of the previous chambers, and the figure may illustrate an embodiment in which multiple heater coils may individually include a shunt capacitor to provide additional plasma tuning. For example, FIG. 8 may include all of the components of FIG. 4, although some are not shown. A pedestal 810 within a processing chamber 805 may include a plurality of embedded heaters 815. The heaters may be similar to those discussed previously with FIG. 5, and may include a number of coils or resistive heaters embedded concentrically within the pedestal. Although the figure illustrates what may appear to be multiple filters off separate cross sections of coils, it is intended to represent a separate filter connected with four separate heater coils, which may be concentrically disposed within the pedestal and extending radially outward.

Exemplary systems may include at least about two, at least about three, at least about four, at least about five, or more heaters within the pedestal. Each of the inlet and outlet lines may extend through a stem of the pedestal and may be individually coupled with a separate RF filter 820 as illustrated. A separate shunt capacitor 825 may be incorporated between each filter and the respective heater as previously discussed. The capacitors may each be a variable capacitor that may have an adjustable capacitance. For example, each capacitor may include a motor operable by control system 830, which may provide instructions to modulate each shunt capacitor individually. By modulating the capacitance of each filter, the impedance within each radial zone may be adjusted, which may allow tuning of the plasma envelope to develop a more uniform volume, such as when electronegative species are produced by the plasma. Producing a more uniform plasma envelope profile may allow a more uniform plasma processes to be performed on a substrate.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing system comprising:
a pedestal positioned within a semiconductor processing chamber and configured to support a substrate, wherein:
the pedestal comprises an electrode operable to form a plasma within a processing region of the semiconductor processing chamber, the processing region at least partially defined by the pedestal,
the pedestal comprises a heater embedded within the pedestal,
the heater is coupled with a power supply,
an RF filter is coupled between the power supply and the heater, and
a shunt capacitor is coupled between the RF filter and the heater.

2. The semiconductor processing system of claim 1, wherein the shunt capacitor comprises a variable capacitor coupled with a motor configured to adjust a capacitance of the variable capacitor.

3. The semiconductor processing system of claim 2, wherein the motor is controlled by a control system configured to perform real-time adjustments to impedance of the heater.

4. The semiconductor processing system of claim 2, wherein the heater comprises a resistive heater including an inlet line and an outlet line, and wherein the inlet line and the outlet line are each coupled with a variable capacitor.

5. The semiconductor processing system of claim 4, wherein the inlet line and the outlet line are each electrically coupled with a single variable capacitor.

6. The semiconductor processing system of claim 1, wherein the power supply comprises an AC power supply.

7. The semiconductor processing system of claim 1, wherein the electrode is coupled with an RF generator configured to operate at about 13.56 MHz.

8. The semiconductor processing system of claim 1, wherein the heater is a first heater, and wherein the semiconductor processing system further comprises a second heater radially inward of the first heater.

9. The semiconductor processing system of claim 8, wherein the RF filter is a first RF filter, wherein the shunt capacitor is a first shunt capacitor, and wherein the second heater is coupled with a second RF filter and a second shunt capacitor individually adjustable separately from the first shunt capacitor.

10. The semiconductor processing system of claim 9, further comprising four heaters each individually electrically coupled with a separate RF filter and a separate shunt capacitor.

11. A method of forming a plasma within a semiconductor processing chamber, the method comprising:
flowing a precursor into a processing region of the semiconductor processing chamber, the processing region being at least partially defined by a pedestal configured to support a substrate, wherein:
the pedestal comprises an electrode operable to form a plasma within the processing region of the semiconductor processing chamber, the processing region at least partially defined by the pedestal,
the pedestal comprises a heater embedded within the pedestal,
the heater is coupled with a power supply,
an RF filter is coupled between the power supply and the heater, and
a shunt capacitor is coupled between the RF filter and the heater; and
forming a plasma of the precursor to produce plasma effluents.

12. The method of forming a plasma of claim 11, further comprising operating a motor coupled with the shunt capacitor to adjust a capacitance of the shunt capacitor.

13. The method of forming a plasma of claim 12, wherein increasing the capacitance of the shunt capacitor reduces an impedance at the heater.

14. The method of forming a plasma of claim 13, wherein the heater is disposed within the pedestal proximate a radial edge of the pedestal, and wherein increasing the capacitance of the shunt capacitor reduces a thickness of an envelope of the plasma proximate the radial edge of the pedestal.

15. The method of forming a plasma of claim 11, wherein the pedestal comprises a ceramic, and wherein the electrode is coupled with an RF generator.

16. The method of forming a plasma of claim 15, wherein the RF generator is configured to operate at 13.56 MHz.

17. The method of forming a plasma of claim 11, further comprising a plurality of heaters, wherein each heater of the plurality of heaters is coupled with a separate RF filter, and wherein a separate shunt capacitor is positioned between each heater and RF filter.

18. The method of forming a plasma of claim 11, wherein the shunt capacitor is coupled as a bypass between the heater and the RF filter.

19. The method of forming a plasma of claim 11, wherein the precursor comprises a halogen-containing precursor.

20. A semiconductor processing system comprising:
a pedestal positioned within a semiconductor processing chamber and configured to support a substrate, wherein:
the pedestal comprises an electrode operable to form a plasma within a processing region of the semiconductor processing chamber, the processing region at least partially defined by the pedestal,
the pedestal comprises a ceramic;
the electrode is coupled with an RF generator configured to operate at 13.56 MHz;
the pedestal comprises a heater embedded within the pedestal,
the heater is coupled with an AC power supply,
an RF filter is coupled between the AC power supply and the heater,
a shunt capacitor is coupled between the RF filter and the heater, and
the shunt capacitor is electrically coupled as a bypass between the RF filter and the heater.
